(19) United States
(12) Patent Application Publication
(10) Pub. No.: US 2014/0006697 A1
(43) Pub. Date: Jan. 2, 2014

(54) MEMORY BANK HAVING WORKING STATE INDICATION FUNCTION

(71) Applicants: Hon Hai Precision Industry Co., Ltd., New Taipei (TW); Hong Fu Jin Precision Industry (ShenZhen) Co., Ltd., Shenzhen (CN)

(72) Inventors: BO TIAN, Shenzhen (CN); KANG WU, Shenzhen (CN)

(21) Appl. No.: 13/922,286

(22) Filed: Jun. 20, 2013

(30) Foreign Application Priority Data
Jun. 28, 2012 (CN) 201210217818X

(51) Int. Cl. G11C 7/10

(52) U.S. Cl. CPC G11C 7/1072
USPC 711/104

(57) ABSTRACT

A memory bank for a computer system includes a state indication unit for indicating the working state of the memory bank. A register chip of the memory bank includes a detection module that detects whether the memory bank works normally or not and generates a control signal for controlling the indication unit. The indication unit connects to the detection module to receive the control signal and indicates whether or not the memory bank works normally using a light indicator.

### BACKGROUND

1. Technical Field

Embodiments of the present disclosure relate to memory banks, and particularly to a memory bank having a working state indication function.

2. Description of Related Art

Many computer systems use a plurality of memory banks to improve performance of the computer systems. It is very important for a computer system to monitor the working state of the memory banks. In some particular solutions, a detection circuit for detecting the working state of the memory bank is designed on a motherboard of the computer system to monitor whether the memory banks work normally or not. However, the detection circuit takes up space on the motherboard, preventing miniaturization of the motherboard. Further, since the detection circuit is designed on the motherboard, a plurality of data lines, which are prone to inaccurate detection due to potential malfunctions, are needed to acquire data from the memory bank. Therefore, there is room for improvement in the art.

### BRIEF DESCRIPTION OF THE DRAWINGS

The FIGURE illustrates a schematic block diagram of one embodiment of a memory bank having a fault indication function.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

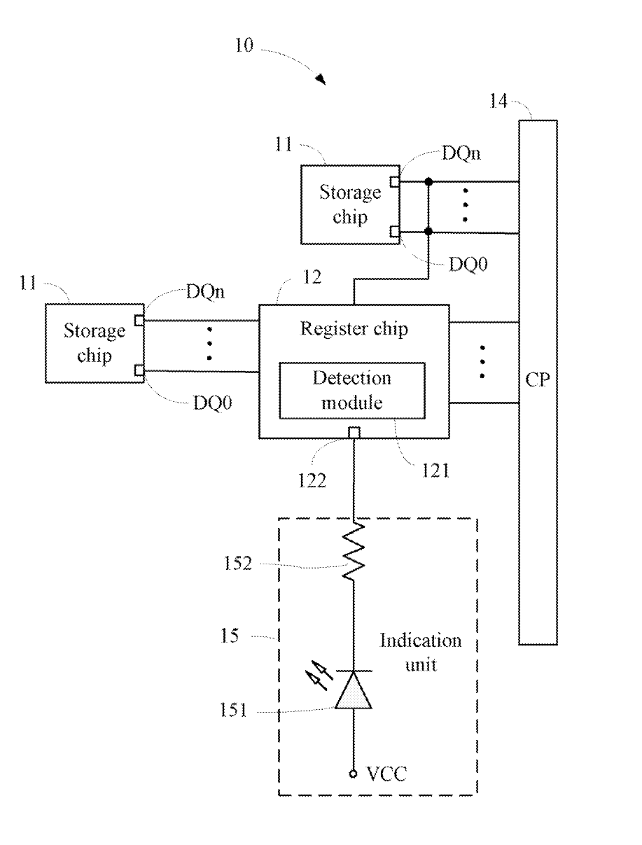

FIG. 1 illustrates a schematic block diagram of one embodiment of a memory bank 10. The memory bank 10 includes at least one storage chip 11, a register chip 12, a connection port (CP) 14, and an indication unit 15. The storage chip 11 may be, for example, a static random access memory (SRAM) chip or a dynamic random access memory (DRAM) chip configured to store data. The storage chip 11 includes a plurality of data input/output (I/O) ports (e.g., DQ0-DQn) connected to the connection port 14. The storage chip 11 receives data input from an external device and/or outputs stored data to the external device through the connection port 14. In the embodiment, the external device is a motherboard of a computer system using the memory bank 10.

The connection port 14 includes a plurality of data transmission pins, which electronically connect to the external device. Thus, the connection port 14 is electronically connected between the storage chip 11 and the external device for data transmission. In the embodiment, the connection port 14 is an edge connector of the storage chip 11 and is inserted into a memory bank socket (e.g., a dual in-line memory module, DIMM) of the motherboard.

The register chip 12 stores parameters for initializing the memory bank 10, such as data transmission rate, capacity, and working voltages of the memory bank 10. The register chip 12 is electronically connected to the indication unit 15 and controls the indication unit 15 to indicate the working state of the memory bank 10.

In this embodiment, the register 12 includes a detection module 121 and an indication terminal 122. The detection module 121 detects whether or not the memory bank 10 works normally and outputs a control signal to the indication unit 15 through the indication terminal 122 to control the indication unit 15 to indicate the working state of the memory bank.

The detection module 121 detects whether or not the memory bank 10 works normally by detecting a logic voltage of each of the data I/O ports of the storage chip 11. For example, when the detected logic voltage of each of the data I/O ports continuously changes between a logic high level voltage (e.g., 2.5V or 3.3V) and a logic low level voltage (e.g., 0V) within a predetermined time period (e.g., 15 or 30 seconds), the detection module 121 determines that the memory bank 10 works normally and outputs a first control signal. Otherwise, when the detected logic voltage of any of the data I/O ports does not change within the predetermined time period, the detection module 121 determines that the memory bank 10 does not work normally and outputs a second control signal. In one embodiment, the first control signal may be a high level voltage signal (e.g., 3.3V), and the second control signal may be a low level voltage signal (e.g., 0V). In another embodiment, the first control signal may be the low level voltage signal, and the second control signal may be the high level voltage signal.

The indication unit 15 includes a light indicator 151 and a current-limiting resistor 152. The light indicator 151 is connected to the indication terminal 122 through the current-limiting resistor 152. When the first control signal (e.g., the high level voltage signal, 3.3V) is transmitted to the light indicator 151 through the indication terminal 122, the light indicator 151 is turned off and does not emit light (e.g., red light), which indicates that the memory bank 10 works normally. When the second control signal (e.g., the low level voltage signal, 0V) is transmitted to the light indicator 151, the light indicator 151 is turned on and emits light, which indicates that the memory bank 10 does not work normally. In the embodiment, the light indicator 151 is a light emitting diode (LED), where an anode of the LED is connected to the indication terminal 122 through the current-limiting resistor 152, and a cathode of the LED is connected to a power supply pin (VCC) to obtain a voltage (e.g., 3V).

Since the detection module 121 is provided in the register chip 12 of the memory bank 10 to detect the working state of the memory bank 10, another detection circuit designed on a motherboard for monitoring the working state of the memory bank can be omitted, which favors the miniaturization design of the motherboard. Further, a plurality of data lines connected between the memory bank and the motherboard are not needed to acquire data from the memory bank, and inaccurate detection due to potential malfunctions of the data lines is avoided.

In addition, Since the indication unit 15 indicates the working state of the memory bank 10, a user can directly and conveniently know whether the memory bank 10 works normally or not according to the light indicator 151.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A memory bank for a computer system, comprising:
at least one storage chip comprising a plurality of data input/output (I/O) ports;
a register chip comprising a detection module and an indication terminal, the detection module detecting a logic voltage of each of the data I/O ports of the at least one storage chip to detect whether or not the memory bank works normally and outputting a control signal through the indication terminal according to the detection of the memory banks; and
an indication unit connected to the indication terminal to receive the control signal and indicate whether the memory bank works normally according to the control signal.

2. The memory bank according to claim 1, wherein when the detected logic voltage of each of the data I/O ports continuously changes between a logic high level voltage and a logic low level voltage within a predetermined time period, the detection module determines that the memory bank works normally and outputs a first control signal; and
when the detected logic voltage of any of the data I/O ports does not change within the predetermined time period, the detection module determines that the memory bank does not work normally and outputs a second control signal.

3. The memory bank according to claim 2, wherein the indication unit comprises a light indicator, when the first control signal is output to the light indicator through the indication terminal, the light indicator is turned off and does not emit light to indicate that the memory bank works normally; and when the second control signal is output to the light indicator, the light indicator is turned on and emits light to indicate that the memory bank does not work normally.

4. The memory bank according to claim 3, wherein indication unit further comprises a current-limiting resistor, the light indicator is connected to the indication terminal through the current-limiting resistor.

5. The memory bank according to claim 4, wherein the light indicator is a light emitting diode (LED), where an anode of the LED is connected to the indication terminal through the current-limiting resistor, and a cathode of the LED is connected to a power supply pin to obtain a voltage.

6. The memory bank according to claim 1, further comprising a connection port having a plurality of connecting pins configured to connect an external device, wherein the at least one storage chip receives data input from the external device and/or outputs stored data to the external device through the connection port.

7. The memory bank according to claim 6, wherein the connection port is an edge connector of the at least one storage chip.

8. The memory bank according to claim 1, wherein the at least one storage chip is a static random access memory (SRAM) chip or a dynamic random access memory (DRAM) chip.
